(19) United States
(12) Patent Application Publication
(10) Pub. No.: US 2026/0344238 A1
(43) Pub. Date: Oct. 29, 2026

(54) DISPLAY DEVICE AND DISPLAY PANEL

(71) Applicant: LG DISPLAY CO., LTD., Seoul (KR)

(72) Inventors: SeungHwan Shin, Paju-si (KR); WonHo Lee, Paju-si (KR)

(21) Appl. No.: 19/554,604

(22) Filed: Mar. 2, 2026

(30) Foreign Application Priority Data
Apr. 25, 2025 (KR) 10-2025-0054635

(51) Int. Cl. H10K 59/35; G09G 3/3225; H10K 59/131

(52) U.S. Cl. CPC H10K 59/353; G09G 3/3225; H10K 59/131; G09G 2300/0413; G09G 2300/0452; G09G 2300/0842; G09G 2320/0233

(57) ABSTRACT

A display device in which at least three subpixels corresponding to the same color and adjacent in a row direction among a plurality of subpixels are connected to the same data line, and one white subpixel of two white subpixels adjacent in the row direction is designed with a flip structure, thereby effectively reducing the number of data channels.

### CROSS REFERENCE TO RELATED APPLICATION

This application claims priority from and the benefit of Korean Patent Application No. 10-2025-0054635, filed on Apr. 25, 2025, which is hereby incorporated by reference for all purposes as if fully set forth herein.

### BACKGROUND

### FIELD

Embodiments of the disclosure relate generally to a display panel and a display device including the same.

### DISCUSSION OF THE BACKGROUND

Recently, an organic light emitting display device, which has been spotlighted as a display device, uses an organic light emitting diode (OLED) as a light emitting element that emits light by itself, thereby having advantages of a fast response speed and a large luminous efficiency, luminance, and viewing angle.

Such a display device has an increasing demand for high resolution and large area, and accordingly, the number of data channels in a data driving circuit is continuously increasing.

However, when the number of data channels supplying a data voltage in the display device increases, the manufacturing cost of the data driving circuit increases, and a size of a bezel area connected to each data channel may increase, and accordingly, efforts to reduce the number of data channels are continuing.

The above information disclosed in this Background section is only for understanding of the background of the inventive concepts, and, therefore, it may contain information that does not constitute prior art.

### SUMMARY

Display devices and display panels according to embodiments of the disclosure are capable of effectively reducing the number of data channels by sharing the same data line among unit pixels adjacent in a row direction.

Additional features of the inventive concepts will be set forth in the description which follows, and in part will be apparent from the description, or may be learned by practice of the inventive concepts.

According to one or more embodiments of the disclosure, a display device includes a display panel on which a plurality of gate lines, a plurality of data lines, and a plurality of subpixels are disposed, a gate driving circuit driving the plurality of gate lines, and a data driving circuit supplying a data voltage to the plurality of data lines. The subpixels include a plurality of white subpixels corresponding to a white color and a plurality of color subpixels corresponding to a plurality of colors except for the white color. At least three subpixels corresponding to the same color and adjacent in a row direction among the plurality of subpixels are connected to the same data line. One white subpixel of two white subpixels adjacent in the row direction among the plurality of white subpixels has a flip structure in which positions of an emission area and a subpixel circuit portion are inverted, and a remaining white subpixel of the two white subpixels adjacent in the row direction may have a normal arrangement structure in which the emission area is above the subpixel circuit portion.

One color subpixel of three color subpixels corresponding to the same color and adjacent in the row direction among the plurality of color subpixels may have the flip structure, and remaining two color subpixels of the three color subpixels adjacent in the row direction may have the normal arrangement structure.

The plurality of gate lines may include a first gate line and a dummy gate line disposed between the data driving circuit and the first gate line.

At least one white subpixel having the flip structure among white subpixels disposed in a first row closest to the data driving circuit among the plurality of white subpixels may be connected to the dummy gate line.

A straight-line distance between the subpixel circuit portion of the white subpixel connected to the dummy gate line and the data driving circuit may be less than a straight-line distance between subpixel circuit portions of remaining white subpixels except for the white subpixel connected to the dummy gate line among the white subpixels disposed in the first row and the data driving circuit.

One white subpixel and three color subpixels corresponding to different colors among the plurality of subpixels may form one unit pixel, and the three color subpixels in the unit pixel may include a first color subpixel corresponding to a first color, a second color subpixel corresponding to a second color, and a third color subpixel corresponding to a third color.

At least three different gate lines may be disposed in the unit pixel.

Sub-pixels disposed in the first row among the plurality of subpixels may form a first pixel group, subpixels disposed in a second row among the plurality of subpixels may form a second pixel group, and the plurality of gate lines may include the dummy gate line disposed in the first pixel group and the second pixel group, and first-to-sixth gate lines.

The first pixel group may include a first unit pixel to a sixth unit pixel sequentially disposed in the row direction, and a white subpixel in a third unit pixel among the first unit pixel to the sixth unit pixel may be connected to the dummy gate line.

One color subpixel among the first color subpixel, the second color subpixel, and the third color subpixel may have the flip structure.

The first color subpixel, the second color subpixel, the white subpixel, and the third color subpixel may be sequentially disposed in the row direction in the unit pixel.

A high-potential voltage line may be disposed in an area adjacent to one side of the first color subpixel and an area adjacent to another side of the third color subpixel on the display panel, and a sensing line may be disposed in an area located between another side of the second color subpixel and one side of the one white subpixel.

The sensing line may be connected to a branch line passing through the emission area of each of the first color subpixel, the second color subpixel, the one white subpixel, and the third color subpixel.

Each of the plurality of data lines may include three sub data lines branched to supply the data voltage to each of three subpixels corresponding to the same color and adjacent in the row direction.

The plurality of color subpixels may include a plurality of red subpixels corresponding to a red color, a plurality of green subpixels corresponding to a green color, and a plurality of blue subpixels corresponding to a blue color.

The plurality of data lines may include at least one white data line connected to the plurality of white subpixels, at least one red data line connected to the plurality of red subpixels, at least one green data line connected to the plurality of green subpixels, and at least one blue data line connected to the blue subpixels.

According to yet another embodiment of the disclosure, a display panel includes a plurality of unit pixels disposed in a row closest to a data driving circuit and each including a white subpixel and at least one color subpixel, a plurality of gate lines each connected to at least one corresponding unit pixel among the plurality of unit pixels, and a plurality of data lines each connected to at least one corresponding unit pixel among the plurality of unit pixels. The plurality of unit pixels may include a first unit pixel, a second unit pixel, a third unit pixel, a fourth unit pixel, a fifth unit pixel, and a sixth unit pixel sequentially disposed in the row closest to the data driving circuit. The plurality of data lines include a first white data line and at least one first color data line each connected to the white subpixel and at least one color subpixel in the first unit pixel to the third unit pixel, and a second white data line and at least one second color data line each connected to the white subpixel and at least one color subpixel in the fourth unit pixel to the sixth unit pixel. One white subpixel of two adjacent white subpixels in the first unit pixel to the sixth unit pixel has a flip structure in which positions of an emission area and a subpixel circuit portion are inverted, and a remaining white subpixel of the two adjacent white subpixels has a normal arrangement structure in which the emission area is above the subpixel circuit portion.

One color subpixel of three adjacent color subpixels corresponding to the same color in the first unit pixel to the sixth unit pixel has the flip structure, and remaining two color subpixels of the three adjacent color subpixels has the normal arrangement structure.

The plurality of gate lines may include first-to-third gate lines and a dummy gate line disposed between the data driving circuit and the first gate line, and the dummy gate line may be connected to the white subpixel in the third unit pixel.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the disclosure, and together with the description serve to explain the inventive concepts.

FIG. 1 is a view illustrating a display device according to embodiments of the disclosure.

FIG. 2 is an equivalent circuit diagram illustrating an example of a subpixel according to embodiments of the disclosure.

FIGS. 3 and 4 are views illustrating a unit pixel in a display device according to embodiments of the disclosure.

FIG. 5 is a view illustrating an example of an arrangement relationship of subpixels according to embodiments of the disclosure.

FIGS. 6 and 7 are views illustrating vertical line defects viewed in a display device according to embodiments of the disclosure.

FIGS. 8, 9, 10 and 11 are views illustrating an example of a driving order of subpixels according to embodiments of the disclosure.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

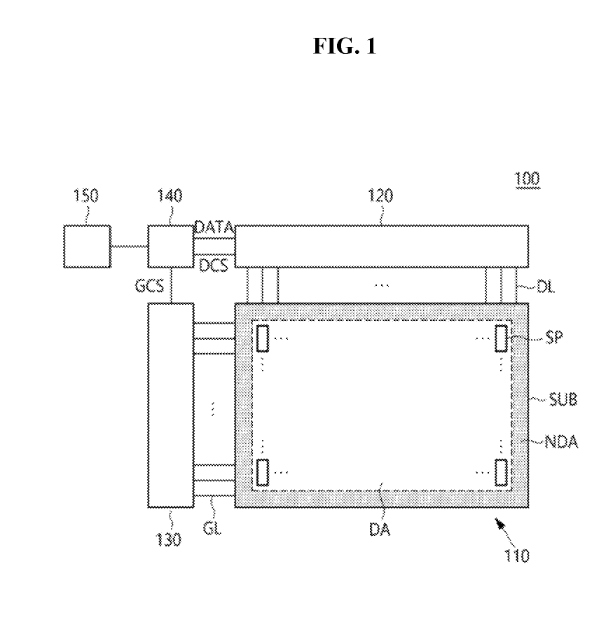

FIG. 1 is a view illustrating a display device according to embodiments of the disclosure.

Referring to FIG. 1, according to embodiments of the disclosure, a display device 100 may include a display panel 110 and driving circuits for driving the display panel 110.

The driving circuits may include a data driving circuit 120 and a gate driving circuit 130. The display device 100 may further include a controller 140 controlling the data driving circuit 120 and the gate driving circuit 130.

The display panel 110 may include a plurality of subpixels SP connected to the plurality of data lines DL and the plurality of gate lines GL.

According to the example of FIG. 1, the plurality of gate lines GL extend in a row direction (e.g., a horizontal direction), and the plurality of data lines DL may extend in a column direction (e.g., a vertical direction).

For example, the plurality of subpixels SP may include a plurality of white subpixels corresponding to a white color and a plurality of color subpixels corresponding to a plurality of colors except for the white color.

For example, the color subpixels may include a red subpixel, a green subpixel, and a blue subpixel corresponding to a red color, a green color, and a blue color, respectively.

However, embodiments of the disclosure are not limited thereto, and the plurality of subpixels SP may also include at least one subpixel corresponding to another color (e.g., magenta, yellow, cyan, etc.) except for the white color, the red color, the green color, and the blue color.

One white subpixel and three color subpixels corresponding to different colors among the plurality of subpixels SP may form one unit pixel. Here, the white subpixel and the three color subpixels of one unit pixel may be sequentially disposed in a row direction.

Hereinafter, for convenience of description, the three color subpixels ofone unit pixel may be referred to as a first color subpixel, a second color subpixel, and a third color subpixel.

At least three subpixels corresponding to the same color and adjacent in a row direction among the subpixels SP according to embodiments of the disclosure may be connected to the same data line.

According to an embodiment, the same data line may be disposed in three unit pixels adjacent in a row direction among the plurality of unit pixels.

Further, at least three gate lines GL may be disposed in each of the plurality of unit pixels.

The controller 140 may supply a data control signal DCS to the data driving circuit 120 to control the operation timing of the data driving circuit 120. Further, the controller 140 may supply a gate control signal GCS for controlling the operation timing of the gate driving circuit 130 to the gate driving circuit 130.

The controller 140 may control to start a scan operation according to a timing implemented in each frame, convert input image data input from the outside (e.g., the host system 150) into image data DATA suited for the data signal format used in the data driving circuit 120, supply the image data DATA to the data driving circuit 120, and control data driving to proceed at an appropriate time according to the scan timing.

Specifically, the controller 140 may receive various timing signals, including a vertical synchronization signal VSYNC, a horizontal synchronization signal HSYNC, a data enable signal DE, and a clock signal CLK, along with the input image data, from the outside (e.g., the host system 150) and generate various control signals DCS and GCS to control the data driving circuit 120 and the gate driving circuit 130 and output them to the data driving circuit 120 and the gate driving circuit 130.

To control the gate driving circuit 130, the controller 140 may output various gate control signals GCS including a gate start pulse GSP, a gate shift clock GSC, and a gate output enable signal GOE.

To control the data driving circuit 120, the controller 140 may output various data control signals DCS including, e.g., a source start pulse SSP, a source sampling clock SSC, and a source output enable signal SOE.

The controller 140 may be implemented as a separate component from the data driving circuit 120, or the controller 140, along with the data driving circuit 120, may be implemented as an integrated circuit.

The data driving circuit 120 may receive the image data DATA from the controller 140 and supply data voltages to the plurality of data lines DL, thereby driving the plurality of data lines DL. Here, the data driving circuit 120 may be described as a source driving circuit.

The data driving circuit 120 may include one or more source driver integrated circuits (SDIC).

For example, each source driver integrated circuit (SDIC) may be connected with the display panel 110 by a tape automated bonding (TAB) type or connected to a bonding pad of the display panel 110 by a chip-on-glass (COG) or chip-on-panel (COP) type or may be implemented by a chip-on-film (COF) type and connected with the display panel 110.

The gate driving circuit 130 may output a gate signal of a turn-on voltage level or a gate signal of a turn-off voltage level according to the control of the controller 140. The gate driving circuit 130 may sequentially drive the plurality of gate lines GL by sequentially supplying gate signals of the turn-on voltage level to the plurality of gate lines GL.

The gate driving circuit 130 may be connected with the display panel 110 by TAB method or connected to a bonding pad of the display panel 110 by a COG or COP method or may be connected with the display panel 110 according to a COF method. Alternatively, the gate driving circuit 130 may be formed in a gate-in-panel (GIP) type, in the non-display area NDA of the display panel 110. The gate driving circuit 130 may be disposed on the substrate SUB or may be connected to the substrate SUB. In other words, the gate driving circuit 130 that is of a GIP type may be disposed in the non-display area NDA of the substrate SUB. The gate driving circuit 130 that is of a chip-on-glass (COG) type or chip-on-film (COF) type may be connected to the substrate SUB.

At least one of the data driving circuit 120 and the gate driving circuit 130 may be disposed in the display area DA. For example, at least one of the data driving circuit 120 and the gate driving circuit 130 may be disposed so as to not overlap a plurality of subpixels SP or to overlap all or some of the plurality of subpixels SP.

When a specific gate line GL is opened by the gate driving circuit 130, the data driving circuit 120 may convert the image data DATA received from the controller 140 into an analog data voltage and supply it to the plurality of data lines DL.

The data driving circuit 120 may be connected to one side (e.g., an upper or lower side) of the display panel 110. Depending on the driving scheme or the panel design scheme, data driving circuits 120 may be connected with both the sides (e.g., both the upper and lower sides) of the display panel 110, or two or more of the four sides of the display panel 110.

The gate driving circuit 130 may be connected to one side (e.g., a left or right side) of the display panel 110. Depending on the driving scheme or the panel design scheme, gate driving circuits 130 may be connected with both sides (e.g., both the left and right sides) of the display panel 110, or two or more of the four sides of the display panel 110.

The controller 140 may be a timing controller used in typical display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor.

The controller 140 may be mounted on a printed circuit board or a flexible printed circuit and may be electrically connected with the data driving circuit 120 and the gate driving circuit 130 through the printed circuit board or the flexible printed circuit.

The display device 100 according to embodiments of the disclosure may be a display including a backlight unit, such as a liquid crystal display, or may be a self-luminous display, such as an organic light emitting diode (OLED) display, a quantum dot display, or a micro light emitting diode (LED) display.

According to an embodiment of the disclosure, when the display device 100 is an OLED display, each subpixel SP may include an organic light emitting diode (OLED), which is self-luminous, as a light emitting element. According to an embodiment of the disclosure, when the display device 100 is a quantum dot display, each subpixel SP may include a light emitting element formed of a quantum dot, which is a self-luminous semiconductor crystal. If the display device 100 according to embodiments of the disclosure is a micro LED display, each subpixel SP may include a micro LED, which is self-luminous and formed of an inorganic material, as the light emitting element.

The display panel 110 according to embodiments of the disclosure may have a top emission structure or a bottom emission structure, and in some cases, may have a double-side emission structure.

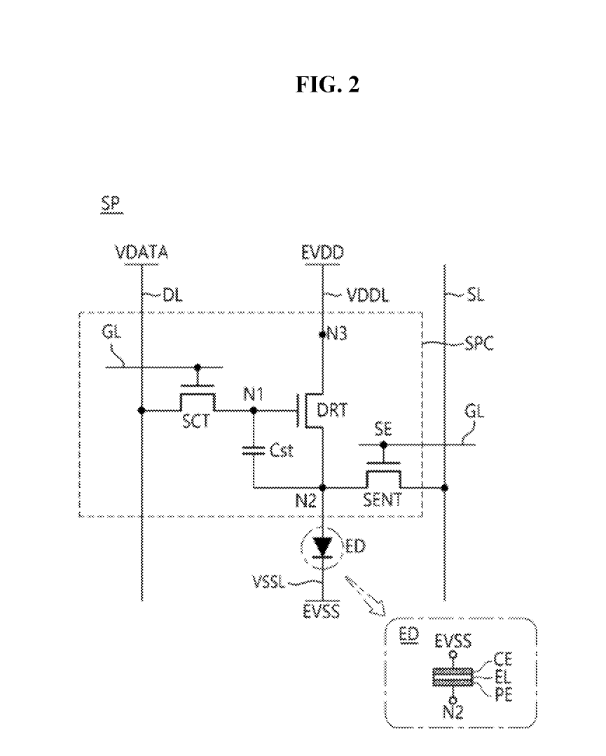

FIG. 2 is an equivalent circuit diagram illustrating an example of a subpixel according to embodiments of the disclosure.

Referring to FIG. 2, the subpixels SP according to embodiments of the disclosure may include a light emitting element ED and a subpixel circuit portion SPC.

The subpixel circuit portion SPC may include a driving transistor DRT for driving a light emitting element ED, a scan transistor SCT connected to a first node N1 of the driving transistor DRT, a sensing transistor SENT connected to a second node N2 of the driving transistor DRT, and a storage capacitor Cst for maintaining a constant voltage during one frame.

The light emitting element ED may include a pixel electrode PE and a common electrode CE, and may further include a light emitting layer EL positioned between the pixel electrode PE and the common electrode CE.

The pixel electrode PE of the light emitting element ED may be an electrode disposed in each subpixel SP, and the common electrode CE may be an electrode commonly disposed in all the subpixels SP.

For example, the pixel electrode PE may be an anode electrode, and the common electrode CE may be a cathode electrode. Conversely, the pixel electrode PE may be a cathode electrode, and the common electrode CE may be an anode electrode.

The common electrode CE of the light emitting element ED may be connected to a low-potential voltage line VSSL that applies a low-potential voltage EVSS.

For example, the light emitting element ED may be an organic light emitting diode (OLED), an inorganic light emitting diode, or a quantum dot light emitting element.

The driving transistor DRT is a transistor for driving the light emitting element ED, and may include a first node N1, a second node N2, and a third node N3.

The first node N1 of the driving transistor DRT may be a gate node of the driving transistor DRT, and may be electrically connected with a source node or a drain node of the scan transistor SCT.

The second node N2 of the driving transistor DRT may be a source node or a drain node of the driving transistor DRT, and may be electrically connected to the pixel electrode PE of the light emitting element ED.

A third node N3 of the driving transistor DRT may be a drain node or a source node of the driving transistor DRT, and may be electrically connected to a high-potential voltage line VDDL supplying a high-potential power voltage EVDD.

The storage capacitor Cst may be electrically connected between the first node N1 and second node N2 of the driving transistor DRT.

The scan transistor SCT is controlled by a gate signal and may be disposed between the first node N1 of the driving transistor DRT and a data line DL.

The scan transistor SCT is turned on by a gate signal having a turn-on voltage level supplied from a gate line GL, and may transfer a data voltage VDATA supplied from the data line DL to the first node N1 of the driving transistor DRT.

The sensing transistor SENT is controlled by a gate signal and may be disposed between the second node N2 of the driving transistor DRT and a sensing line SL.

In other words, the sensing transistor SENT is turned on by a gate signal having a turn-on voltage level supplied from the gate line GL, and may control connection between the sensing line SL and the second node N2 of the driving transistor DRT.

As shown in FIG. 2, the gate node SE of the sensing transistor SENT is connected to the gate line GL, thus the sensing transistor SENT is turned on by a gate signal having a turn-on voltage level, and may transfer a reference voltage supplied through the sensing line SL to the second node N2 of the driving transistor DRT.

Further, the sensing transistor SENT is turned on by a gate signal having a turn-on voltage level, and may transfer the voltage of the second node N2 of the driving transistor DRT to the sensing line SL.

A function of the sensing transistor SENT transferring the voltage of the second node N2 to the sensing line SL may be used during driving for sensing characteristic values (e.g., a threshold voltage, mobility, etc. of the driving transistor DRT) of the subpixel SP. In this case, the voltage transferred to the sensing line SL may be a voltage for calculating the characteristic values of the subpixel SP or a voltage reflecting the characteristic values of the subpixel SP.

According to the example of FIG. 2, the scan transistor SCT and the sensing transistor SENT may be connected to the same gate line GL.

On the other hand, the scan transistor SCT and the sensing transistor SENT may also be connected to different gate lines GL. In this case, the scan transistor SCT may control connection between the data line DL and the first node N1 of the driving transistor DRT by receiving scan gate signal having a turn-on voltage level from a scan gate line, which is a type of the gate line GL, and the sensing transistor SENT may control connection between the sensing line SL and the second node N2 of the driving transistor DRT by receiving sensing gate signal having a turn-on voltage level from a sensing gate line, which is a type of the gate line GL.

Each of the driving transistor DRT, the scan transistor SCT, and the sensing transistor SENT may be an n-type transistor or a p-type transistor. In embodiments of the disclosure, for convenience of description, each of the driving transistor DRT, the scan transistor SCT, and the sensing transistor SENT is exemplified as being n-type.

The structure of the subpixel SP illustrated in FIG. 2 is only one example, and may be variously modified by further including one or more transistors or further including one or more capacitors.

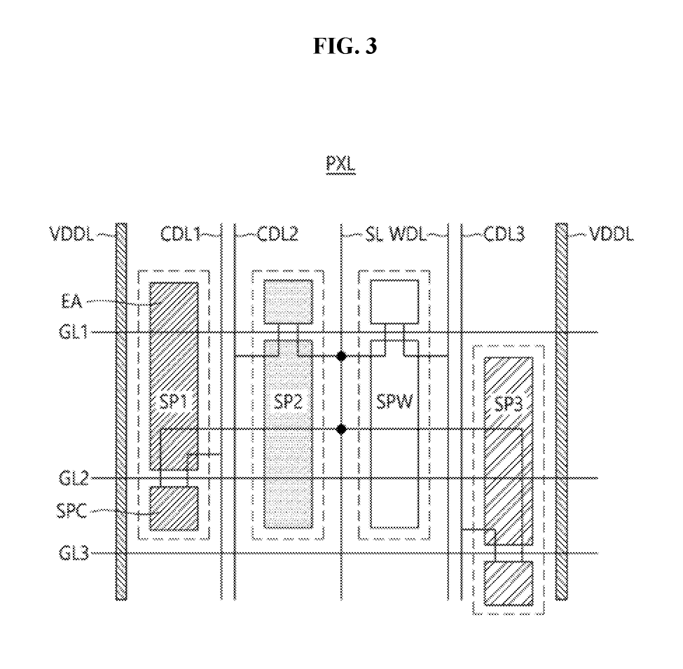

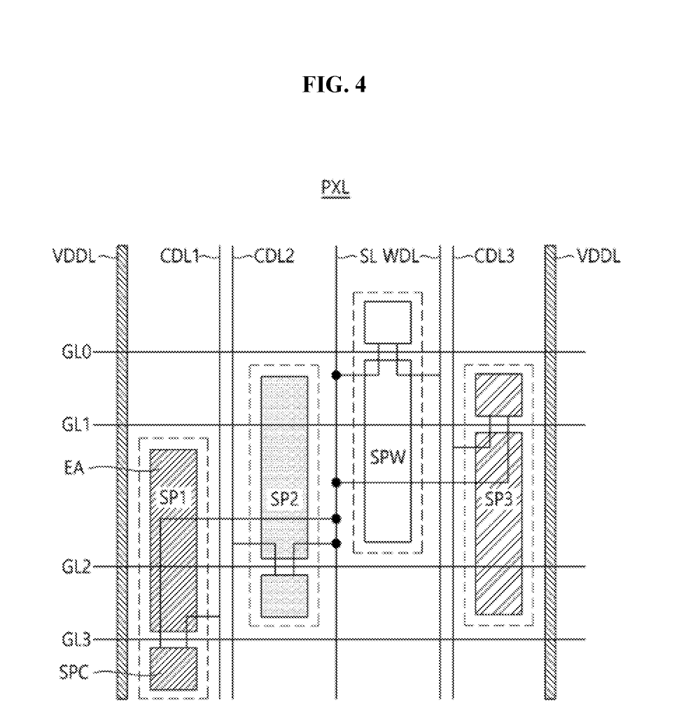

FIGS. 3 and 4 are views illustrating a unit pixel in a display device according to embodiments of the disclosure.

In FIGS. 3 and 4, for convenience of description, one unit pixel PXL disposed in a first row closest to a data driving circuit 120 is exemplified and described.

Referring to FIG. 3, one unit pixel PXL may be designed with a four-subpixel structure including a white subpixel SPW, a first color subpixel SP1 corresponding to a first color, a second color subpixel SP2 corresponding to a second color, and a third color subpixel SP3 corresponding to a third color.

For example, the first color may be a red color, the second color may be a green or blue color, and the third color may be a blue or green color.

Alternatively, the first color may be a green color, the second color may be a red or blue color, and the third color may be a blue or red color.

Alternatively, the first color may be a blue color, the second color may be a green or red color, and the third color may be a red or green color.

Hereinafter, for convenience of description, the first color subpixel SP1 is exemplified as a red subpixel, the second color subpixel SP2 is exemplified as a green subpixel, and the third color subpixel SP3 is exemplified as a blue subpixel.

According to the example of FIG. 3, the first color subpixel SP1, the second color subpixel SP2, the white subpixel SPW, and the third color subpixel SP3 may be sequentially disposed in a row direction in one unit pixel PXL, but embodiments of the disclosure are not limited thereto, and positions of any one color subpixel among the first color subpixel SP1, the second color subpixel SP2, and the third color subpixel SP3 and the white subpixel SPW may be interchanged with each other.

Each of the first color subpixel SP1, the second color subpixel SP2, the white subpixel SPW, and the third color subpixel SP3 may include an emission area EA and a subpixel circuit portion SPC located above or below the emission area EA. Wherein, the emission area EA in FIG. 3 corresponds to an area in which the light emitting element ED in FIG. 2 is located.

Each of the first color subpixel SP1, the second color subpixel SP2, the white subpixel SPW, and the third color subpixel SP3 may be designed with a normal arrangement structure in which a subpixel circuit portion SPC is disposed below an emission area EA, or a flip structure in which a subpixel circuit portion SPC is disposed above an emission area EA.

According to an embodiment, one color subpixel among the first color subpixel SP1, the second color subpixel SP2, and the third color subpixel SP3 in one unit pixel PXL may be designed with a flip structure, and the remaining two color subpixels may be designed with a normal arrangement structure.

According to the example of FIG. 3, the first color subpixel SP1 and the third color subpixel SP3 may be designed with a normal arrangement structure, and the second color subpixel SP2 may be designed with a flip structure.

According to the example of FIG. 3, one unit pixel PXL may be connected to a plurality of data lines CDL1, CDL2, WDL, and CDL3, a high-potential voltage line VDDL, and a sensing line SL.

The plurality of data lines CDL1, CDL2, WDL, and CDL3 connected to one unit pixel PXL may include a first color data line CDL1 connected to the first color subpixel SP1, a second color data line CDL2 connected to the second color subpixel SP2, a white data line WDL connected to the white subpixel SPW, and a third color data line CDL3 connected to the third color subpixel SP3.

For example, when the first color subpixel SP1, the second color subpixel SP2, and the third color subpixel SP3 are a red subpixel, a green subpixel, and a blue subpixel, respectively, the first color data line CDL1, the second color data line CDL2, and the third color data line CDL3 may be a red data line, a green data line, and a blue data line, respectively.

According to the example of FIG. 3, the first color data line CDL1 and the second color data line CDL2 may be disposed in an area located between another side of the first color subpixel SP1 and one side of the second color subpixel SP2, and the white data line WDL and the third color data line CDL3 may be disposed in an area located between another side of the white subpixel SPW and one side of the third color subpixel SP3.

The high-potential voltage line VDDL may be disposed in an area adjacent to one side of the first color subpixel SP1 and an area adjacent to another side of the third color subpixel SP3.

The high-potential voltage line VDDL may be connected to the subpixel circuit portion SPC of each subpixel SP1, SP2, SPW, and SP3 through at least one first branch line.

The sensing line SL may be disposed in an area located between another side of the second color subpixel SP2 and one side of the white subpixel SPW, and may be connected to a second branch line passing through the emission area EA of each of the first color subpixel SP1, the second color subpixel SP2, the white subpixel SPW, and the third color subpixel SP3.

In other words, the sensing line SL may be connected to the subpixel circuit portion SPC in each subpixel SP1, SP2, SPW, and SP3 through the second branch line passing through the emission area EA.

For example, the second branch line may be a transparent line and may be disposed in a different layer from the plurality of data lines CDL1, CDL2, WDL, and CDL3.

Three different gate lines GL1, GL2, and GL3 may be disposed in one unit pixel PXL.

According to the example of FIG. 3, the second color subpixel SP2 and the white subpixel SPW may be connected to a first gate line GL1, the first color subpixel SP1 may be connected to a second gate line GL2, and the third color subpixel SP3 may be connected to a third gate line GL3.

Referring to FIG. 4, the display panel 110 according to embodiments of the disclosure may further include a dummy gate line GL0. Here, the dummy gate line GL0 may be disposed between the data driving circuit 120 and the first gate line GL1.

According to the example of FIG. 4, four different gate lines GL0, GL1, GL2, and GL3 may be disposed in one unit pixel PXL disposed in the first row.

According to the example of FIG. 4, the white subpixel SPW may be connected to the dummy gate line GL0, the third color subpixel SP3 may be connected to the first gate line GL1, the second color subpixel SP2 may be connected to the second gate line GL2, and the first color subpixel SP1 may be connected to the third gate line GL3.

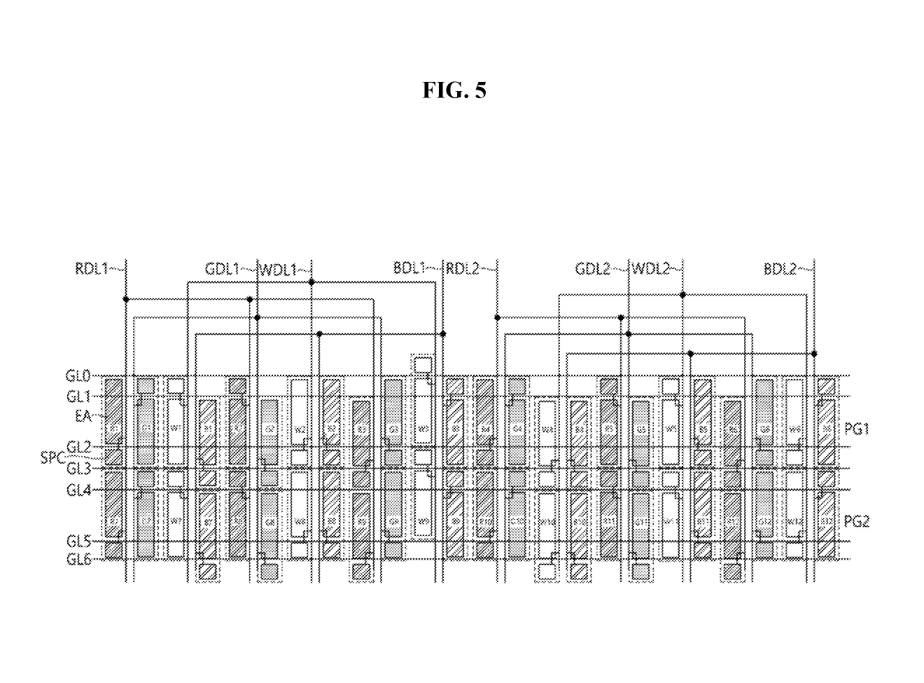

FIG. 5 is a view illustrating an example of an arrangement relationship of subpixels according to embodiments of the disclosure.

Referring to FIG. 5, subpixels disposed in a first row among the plurality of subpixels according to embodiments of the disclosure may form a first pixel group PG1, and subpixels disposed in a second row may form a second pixel group PG2.

According to the example of FIG. 5, the first pixel group PG1 may include a first unit pixel (R1, G1, W1, B1), a second unit pixel (R2, G2, W2, B2), a third unit pixel (R3, G3, W3, B3), a fourth unit pixel (R4, G4, W4, B4), a fifth unit pixel (R5, G5, W5, B5), and a sixth unit pixel (R6, G6, W6, B6).

Further, the second pixel group PG2 may include a seventh unit pixel (R7, G7, W7, B7), an eighth unit pixel (R8, G8, W8, B8), a ninth unit pixel (R9, G9, W9, B9), a tenth unit pixel (R10, G10, W10, B10), an eleventh unit pixel (R11, G11, W11, B11), and a twelfth unit pixel (R12, G12, W12, B12).

In FIG. 5, for convenience of description, only the first-to-twelfth unit pixels disposed in a 2 × 6 matrix form are illustrated, and the arrangement relationship of the first-to-twelfth unit pixels disposed in the 2 × 6 matrix form may be repeated on the display panel 110 according to embodiments of the disclosure.

According to an embodiment, three adjacent unit pixels among the plurality of unit pixels included in each of the first pixel group PG1 and the second pixel group PG2 may share the same data line.

According to the example of FIG. 5, the plurality of data lines corresponding to the first pixel group PG1 and the second pixel group PG2 may include a first red data line RDL1, a first green data line GDL1, a first white data line WDL1, a first blue data line BDL1, a second red data line RDL2, a second green data line GDL2, a second white data line WDL2, and a second blue data line BDL2.

For example, the first-to-third unit pixels and the seventh-to-ninth unit pixels may share the first red data line RDL1, the first green data line GDL1, the first white data line WDL1, and the first blue data line BDL1.

Further, the fourth-to-sixth unit pixels and the tenth-to-twelfth unit pixels may share the second red data line RDL2, the second green data line GDL2, the second white data line WDL2, and the second blue data line BDL2.

According to an embodiment, each of the plurality of data lines may include three sub data lines branched to supply a data voltage to each of three subpixels corresponding to the same color and adjacent in a row direction.

According to the example of FIG. 5, the first red data line RDL1 is connected to a first red channel pad in the data driving circuit 120 and is branched into three sub lines, and each of the branched three sub lines may be disposed in the first and seventh unit pixels, the second and eighth unit pixels, and the third and ninth unit pixels.

Accordingly, the first red data line RDL1 may provide a data voltage supplied from the first red channel pad to each of the first-to-third red subpixels R1, R2, and R3 and the seventh-to-ninth red subpixels R7, R8, and R9.

The first green data line GDL1 is connected to a first green channel pad in the data driving circuit 120 and is branched into three sub lines, and each of the branched three sub lines may be disposed in the first and seventh unit pixels, the second and eighth unit pixels, and the third and ninth unit pixels.

Accordingly, the first green data line GDL1 may provide a data voltage supplied from the first green channel pad to each of the first-to-third green subpixels G1, G2, and G3 and the seventh-to-ninth green subpixels G7, G8, and G9.

The first white data line WDL1 is connected to a first white channel pad in the data driving circuit 120 and is branched into three sub lines, and each of the branched three sub lines may be disposed in the first and seventh unit pixels, the second and eighth unit pixels, and the third and ninth unit pixels.

Accordingly, the first white data line WDL1 may provide a data voltage supplied from the first white channel pad to each of the first-to-third white subpixels W1, W2, and W3 and the seventh-to-ninth white subpixels W7, W8, and W9.

The first blue data line BDL1 is connected to a first blue channel pad in the data driving circuit 120 and is branched into three sub lines, and each of the branched three sub lines may be disposed in the first and seventh unit pixels, the second and eighth unit pixels, and the third and ninth unit pixels.

Accordingly, the first blue data line BDL1 may provide a data voltage supplied from the first blue channel pad to each of the first-to-third blue subpixels B1, B2, and B3 and the seventh-to-ninth blue subpixels B7, B8, and B9.

The second red data line RDL2 is connected to a second red channel pad in the data driving circuit 120 and is branched into three sub lines, and each of the branched three sub lines may be disposed in the fourth and tenth unit pixels, the fifth and eleventh unit pixels, and the sixth and twelfth unit pixels.

Accordingly, the second red data line RDL2 may provide a data voltage supplied from the second red channel pad to each of the fourth-to-sixth red subpixels R4, R5, and R6 and the tenth-to-twelfth red subpixels R10, R11, and R12.

The second green data line GDL2 is connected to a second green channel pad in the data driving circuit 120 and is branched into three sub lines, and each of the branched three sub lines may be disposed in the fourth and tenth unit pixels, the fifth and eleventh unit pixels, and the sixth and twelfth unit pixels.

Accordingly, the second green data line GDL2 may provide a data voltage supplied from the second green channel pad to each of the fourth-to-sixth green subpixels G4, G5, and G6 and the tenth-to-twelfth green subpixels G10, G11, and G12.

The second white data line WDL2 is connected to a second white channel pad in the data driving circuit 120 and is branched into three sub lines, and each of the branched three sub lines may be disposed in the fourth and tenth unit pixels, the fifth and eleventh unit pixels, and the sixth and twelfth unit pixels.

Accordingly, the second white data line WDL2 may provide a data voltage supplied from the second white channel pad to each of the fourth-to-sixth white subpixels W4, W5, and W6 and the tenth-to-twelfth white subpixels W10, W11, and W12.

The second blue data line BDL2 is connected to a second blue channel pad in the data driving circuit 120 and is branched into three sub lines, and each of the branched three sub lines may be disposed in the fourth and tenth unit pixels, the fifth and eleventh unit pixels, and the sixth and twelfth unit pixels.

Accordingly, the second blue data line BDL2 may provide a data voltage supplied from the second blue channel pad to each of the fourth-to-sixth blue subpixels B4, B5, and B6 and the tenth-to-twelfth blue subpixels B10, B11, and B12.

According to an embodiment, the plurality of white subpixels may be designed with a 1:1 flip structure in which one white subpixel of two adjacent white subpixels has a flip structure and another white subpixel has a normal arrangement structure.

According to the example of FIG. 5, a first white subpixel W1, a third white subpixel W3, and a fifth white subpixel W5 among the white subpixels W1 to W6 disposed in the first pixel group PG1 may be designed with a flip structure, and a second white subpixel W2, a fourth white subpixel W4, and a sixth white subpixel W6 may be designed with a normal arrangement structure.

According to an embodiment, the plurality of color subpixels may be designed with a 1:2 flip structure in which one color subpixel of three color subpixels corresponding to the same color and adjacent in a row direction has a flip structure and the remaining two color subpixels have a normal arrangement structure.

According to the example of FIG. 5, a second red subpixel R2 and a fifth red subpixel R5 among the red subpixels R1 to R6 disposed in the first pixel group PG1 may be designed with a flip structure, and a first red subpixel R1, a third red subpixel R3, a fourth red subpixel R4, and a sixth red subpixel R6 may be designed with a normal arrangement structure.

Further, a first green subpixel G1 and a fourth green subpixel G4 among the green subpixels G1 to G6 disposed in the first pixel group PG1 may be designed with a flip structure, and a second green subpixel G2, a third green subpixel G3, a fifth green subpixel G5, and a sixth green subpixel G6 may be designed with a normal arrangement structure.

Further, a third blue subpixel B3 and a sixth blue subpixel B6 among the blue subpixels B1 to B6 disposed in the first pixel group PG1 may be designed with a flip structure, and a first blue subpixel B1, a second blue subpixel B2, a fourth blue subpixel B4, and a fifth blue subpixel B5 may be designed with a normal arrangement structure.

According to the example of FIG. 5, a dummy gate line GL0 and first-to-sixth gate lines GL1 to GL6 may be disposed in the first pixel group PG1 and the second pixel group PG2.

The dummy gate line GL0 may be connected to at least one white subpixel among the white subpixels W1 to W6 disposed in the first pixel group PG1.

Specifically, the dummy gate line GL0 may be connected to at least one white subpixel designed with a flip structure among the white subpixels W1 to W6 disposed in the first pixel group PG1.

According to the example of FIG. 5, the dummy gate line GL0 may be connected to a third white subpixel W3 in a third unit pixel among the first-to-sixth unit pixels in the first pixel group PG1, but the inventive concepts are not limited thereto.

According to an embodiment, a straight-line distance between the subpixel circuit portion SPC of the white subpixel connected to the dummy gate line GL0 and the data driving circuit 120 may be shorter than a straight-line distance between the subpixel circuit portion SPC of another white subpixel in the first pixel group PG1 and the data driving circuit 120.

In other words, the subpixel circuit portion SPC of the third white subpixel W3 connected to the dummy gate line GL0 may be disposed closer to the data driving circuit 120 than the subpixel circuit portions SPC of other white subpixels W1, W2, W4, W5, and W6 in the first pixel group PG1.

According to the example of FIG. 5, a first gate line GL1 may be connected to a first green subpixel G1, a first white subpixel W1, a second red subpixel R2, a third blue subpixel B3, a fourth green subpixel G4, a fifth red subpixel R5, a fifth white subpixel W5, and a sixth blue subpixel B6 in the first pixel group PG1.

A second gate line GL2 may be connected to a first red subpixel R1, a second white subpixel W2, a second blue subpixel B2, a third green subpixel G3, a fourth red subpixel R4, a fifth blue subpixel B5, a sixth green subpixel G6, and a sixth white subpixel W6 in the first pixel group PG1.

A third gate line GL3 may be connected to a first blue subpixel B1, a second green subpixel G2, a third red subpixel R3, a fourth white subpixel W4, a fourth blue subpixel B4, a fifth green subpixel G5, and a sixth red subpixel R6 in the first pixel group PG1, and a ninth white subpixel W9 in the second pixel group PG2.

A fourth gate line GL4 may be connected to a seventh green subpixel G7, a seventh white subpixel W7, an eighth red subpixel R8, a ninth blue subpixel B9, a tenth green subpixel G10, an eleventh red subpixel R11, an eleventh white subpixel W11, and a twelfth blue subpixel B12 in the second pixel group PG2.

A fifth gate line GL5 may be connected to a seventh red subpixel R7, an eighth white subpixel W8, an eighth blue subpixel B8, a ninth green subpixel G9, a tenth red subpixel R10, an eleventh blue subpixel B11, a twelfth green subpixel G12, and a twelfth white subpixel W12 in the second pixel group PG2.

A sixth gate line GL6 may be connected to a seventh blue subpixel B7, an eighth green subpixel G8, a ninth red subpixel R9, a tenth white subpixel W10, a tenth blue subpixel B10, an eleventh green subpixel G11, and a twelfth red subpixel R12 in the second pixel group PG2.

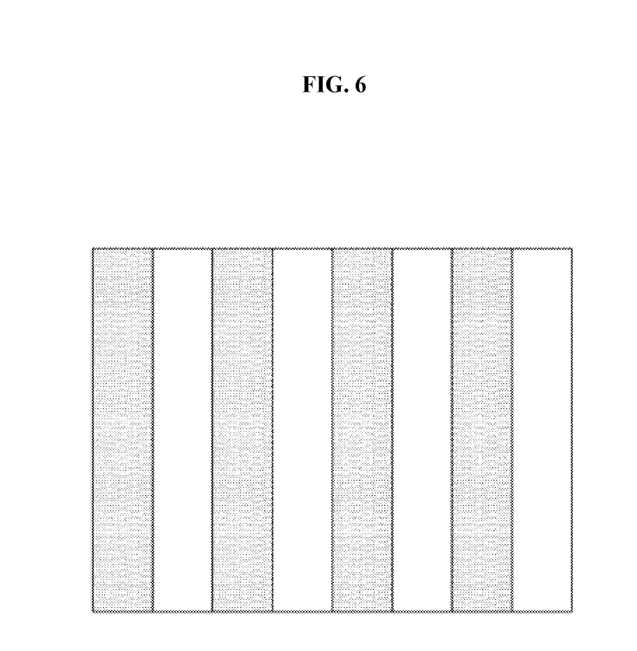

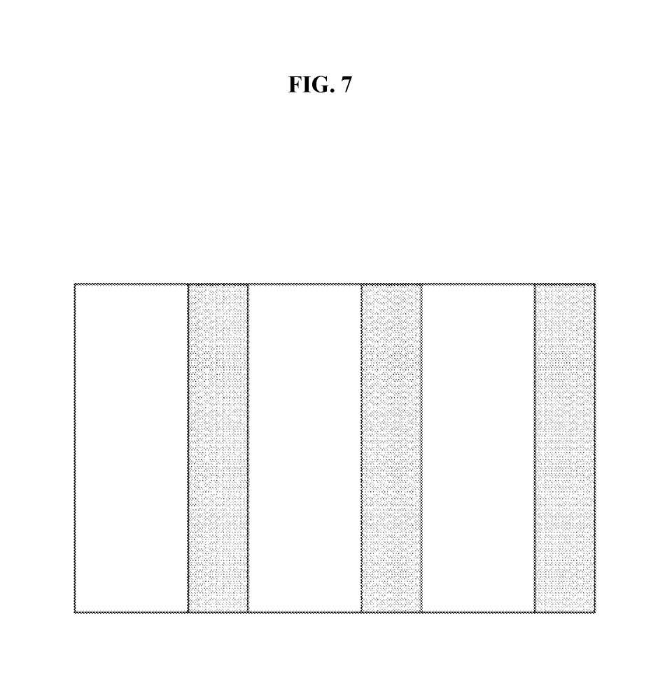

FIGS. 6 and 7 are views illustrating vertical line defects viewed in a display device according to embodiments of the disclosure.

Specifically, FIG. 6 illustrates an example of vertical line defects at 1:1 intervals viewed through the display panel 110, and FIG. 7 illustrates an example of vertical line defects at 1:2 intervals viewed through the display panel 110.

Referring to FIGS. 6 and 7, vertical line defects viewed through the display panel 110 inevitably increase as the interval between bright lines and dark lines becomes larger (e.g., 1:2 intervals) rather than equal intervals (i.e., 1:1 intervals), and the perception level of such defects is more greatly perceived in a gray state than in a color (RGB) state when having the same grayscale.

In other words, in the display device 100 based on four subpixels, the perception level of vertical line defects may be determined by the white subpixel that has the greatest influence on the luminance of the display image.

Accordingly, the display device 100 according to embodiments of the disclosure may be designed such that the white subpixel is driven with regularity by designing the white subpixel with a 1:1 flip structure, thereby minimizing occurrence of vertical line defects. Further, by designing a plurality of color subpixels with a 1:2 flip structure, it can further minimize occurrence of vertical line defects.

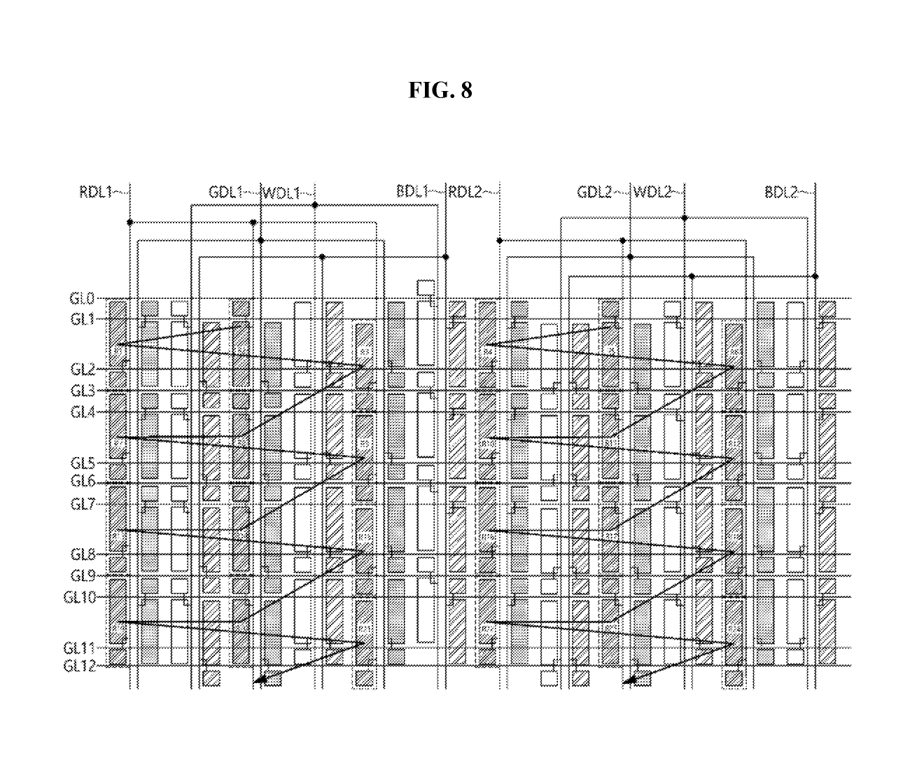

FIGS. 8-11 are views illustrating an example of a driving order of subpixels according to embodiments of the disclosure.

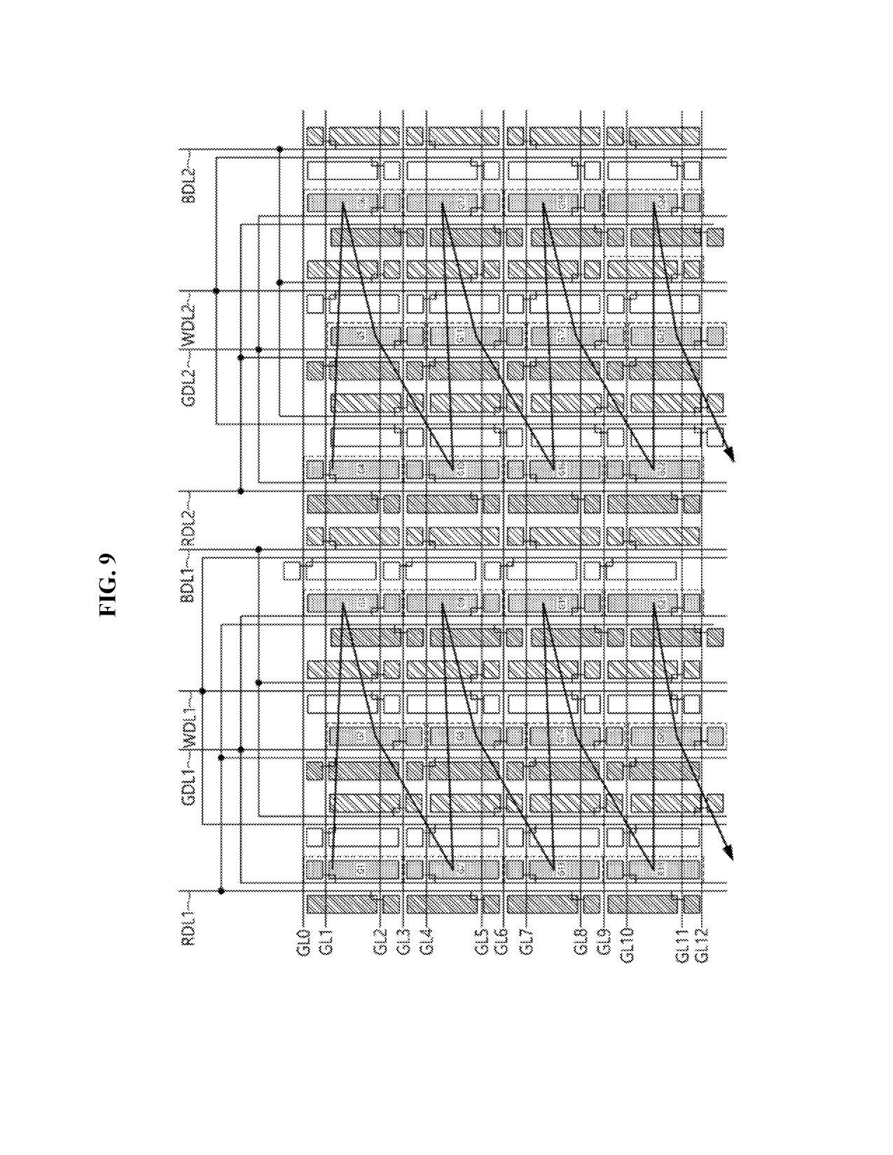

Specifically, FIG. 8 illustrates an example of a driving order of the first to twenty-fourth red subpixels R1 to R24 disposed in a row direction and a column direction, and FIG. 9 illustrates an example of a driving order of the first to twenty-fourth green subpixels G1 to G24 disposed in a row direction and a column direction.

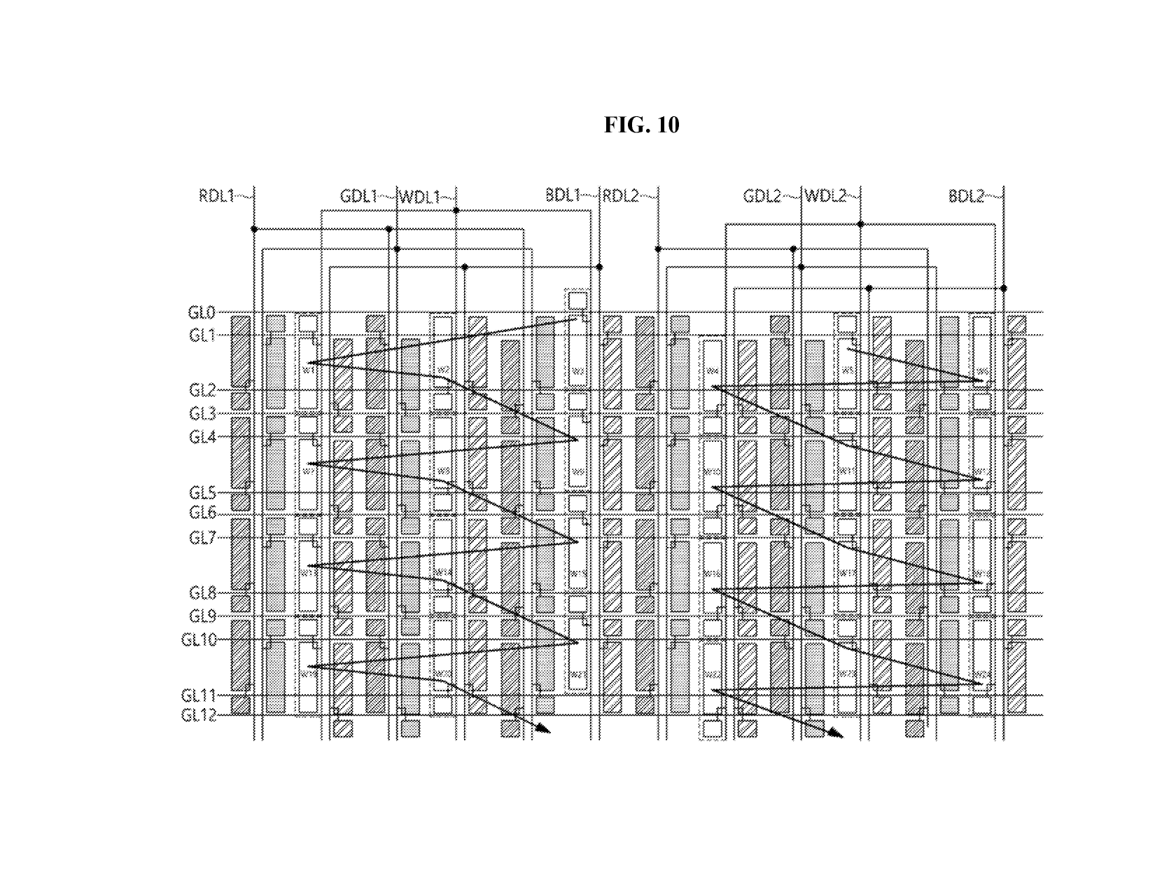

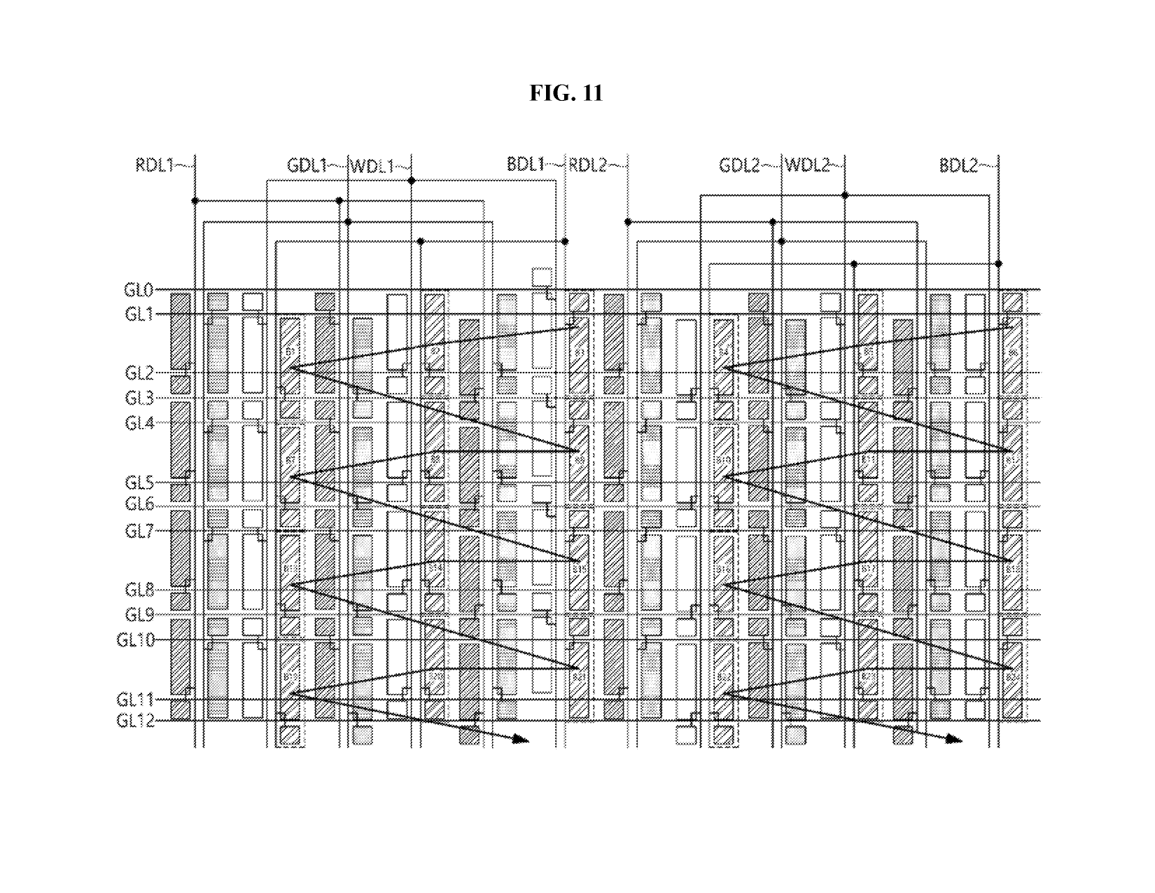

Further, FIG. 10 illustrates an example of a driving order of the first to twenty-fourth white subpixels W1 to W24 disposed in a row direction and a column direction, and FIG. 11 illustrates an example of a driving order of the first to twenty-fourth blue subpixels B1 to B24 disposed in a row direction and a column direction.

Referring to FIGS. 8-11, in the display device 100 according to embodiments of the disclosure, when a data voltage is supplied through a data line connected to at least one subpixel among the plurality of subpixels and a gate signal having a turn-on voltage level is applied through a gate line connected to the at least one subpixel, the at least one subpixel may be driven (e.g., charged and emit light).

According to the example of FIG. 8, when a data voltage is supplied through the first and second red data lines RDL1 and RDL2 and a gate signal having a turn-on voltage level is sequentially applied to the first to twelfth gate lines GL1 to GL12, the second and fifth red subpixels R2 and R5, the first and fourth red subpixels R1 and R4, the third and sixth red subpixels R3 and R6, the eighth and eleventh red subpixels R8 and R11, the seventh and tenth red subpixels R7 and R10, the ninth and twelfth red subpixels R9 and R12, the fourteenth and seventeenth red subpixels R14 and R17, the thirteenth and sixteenth red subpixels R13 and R16, the fifteenth and eighteenth red subpixels R15 and R18, the twentieth and twenty-third red subpixels R20 and R23, the nineteenth and twenty-second red subpixels R19 and R22, and the twenty-first and twenty-fourth red subpixels R21 and R24, which are connected to the first-to-twelfth gate lines GL1 to GL12, respectively, may be sequentially driven.

According to the example of FIG. 9, when a data voltage is supplied through the first and second green data lines GDL1 and GDL2 and a gate signal having a turn-on voltage level is sequentially applied to the first-to-twelfth gate lines GL1 to GL12, the first and fourth green subpixels G1 and G4, the third and sixth green subpixels G3 and G6, the second and fifth green subpixels G2 and G5, the seventh and tenth green subpixels G7 and G10, the ninth and twelfth green subpixels G9 and G12, the eighth and eleventh green subpixels G8 and G11, the thirteenth and sixteenth green subpixels G13 and G16, the fifteenth and eighteenth green subpixels G15 and G18, the fourteenth and seventeenth green subpixels G14 and G17, the nineteenth and twenty-second green subpixels G19 and G22, the twenty-first and twenty-fourth green subpixels G21 and G24, and the twentieth and twenty-third green subpixels G20 and G23, which are connected to the first-to-twelfth gate lines GL1 to GL12, respectively, may be sequentially driven.

According to the example of FIG. 10, when a data voltage is supplied through the first and second white data lines WDL1 and WDL2 and a gate signal having a turn-on voltage level is sequentially applied to the dummy gate line GL0 and the first-to-twelfth gate lines GL1 to GL12, the third white subpixel W3, the first and fifth white subpixels W1 and W5, the second and sixth white subpixels W2 and W6, the ninth and fourth white subpixels W9 and W4, the seventh and eleventh white subpixels W7 and W11, the eighth and twelfth white subpixels W8 and W12, the fifteenth and tenth white subpixels W15 and W10, the thirteenth and seventeenth white subpixels W13 and W17, the fourteenth and eighteenth white subpixels W14 and W18, the twenty-first and sixteenth white subpixels W21 and W16, the nineteenth and twenty-third white subpixels W19 and W23, the twentieth and twenty-fourth white subpixels W20 and W24, and the twenty-second white subpixel W22, which are connected to the dummy gate line GL0 and the first-to-twelfth gate lines GL1 to GL12, respectively, may be sequentially driven.

According to the example of FIG. 11, when a data voltage is supplied through the first and second blue data lines BDL1 and BDL2 and a gate signal having a turn-on voltage level is sequentially applied to the first-to-twelfth gate lines GL1 to GL12, the third and sixth blue subpixels B3 and B6, the second and fifth blue subpixels B2 and B5, the first and fourth blue subpixels B1 and B4, the ninth and twelfth blue subpixels B9 and B12, the eighth and eleventh blue subpixels B8 and B11, the seventh and tenth blue subpixels B7 and B10, the fifteenth and eighteenth blue subpixels B15 and B18, the fourteenth and seventeenth blue subpixels B14 and B17, the thirteenth and sixteenth blue subpixels B13 and B16, the twenty-first and twenty-fourth blue subpixels B21 and B24, the twentieth and twenty-third blue subpixels B20 and B23, and the nineteenth and twenty-second blue subpixels B19 and B22, which are connected to the first-to-twelfth gate lines GL1 to GL12, respectively, may be sequentially driven.

According to an embodiment, at least two subpixels among a red subpixel, a green subpixel, a white subpixel, and a blue subpixel connected to the same gate line may be driven at the same timing.

Embodiments of the disclosure provide a display device and a display panel capable of effectively reducing the number of data channels by sharing the same data line among unit pixels adjacent in a row direction.

Embodiments of the disclosure provide a display device and a display panel capable of minimizing occurrence of vertical line defects due to luminance deviation and driving with low power by designing a plurality of color subpixels with a 1:2 flip structure and designing a plurality of white subpixels with a 1:1 flip structure on a display panel.

Embodiments of the disclosure provide a display device and a display panel capable of optimizing a driving operation of a plurality of white subpixels designed with a 1:1 flip structure by additionally disposing a dummy gate line between a data driving circuit and a first row and driving at least one white subpixel disposed in the first row through the dummy gate line.

Embodiments of the disclosure provide a display device and a display panel capable of reducing the weight of the display device, reducing manufacturing costs, and securing spatial margin by minimizing the number of data channels.

Embodiments of the disclosure provide a display device and a display panel capable of shortening a time for sensing a subpixel by sensing a plurality of colors with one scan operation.

Embodiments of the disclosure provide a display device and a display panel capable of minimizing occurrence of RC delay due to sharing of a data line, enabling frame inversion driving to secure charging characteristics, and enhancing heat generation characteristics through optimization of an arrangement and connection structure of a plurality of subpixels and data/gate lines.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a display panel on which a plurality of gate lines, a plurality of data lines, and a plurality of subpixels are disposed;
a gate driving circuit configured to drive the plurality of gate lines; and
a data driving circuit configured to supply a data voltage to the plurality of data lines,
wherein:
the plurality of subpixels include a plurality of white subpixels corresponding to a white color and a plurality of color subpixels corresponding to a plurality of colors except for the white color;
at least three subpixels corresponding to the same color and adjacent in a row direction among the plurality of subpixels are connected to the same data line; and
one white subpixel of two white subpixels adjacent in the row direction among the plurality of white subpixels has a flip structure in which positions of an emission area and a subpixel circuit portion are inverted.

2. The display device of claim 1, wherein one color subpixel of three color subpixels corresponding to the same color and adjacent in the row direction among the plurality of color subpixels has the flip structure. and remaining two color subpixels of the three color subpixels adjacent in the row direction has the normal arrangement structure.

3. The display device of claim 1, wherein the plurality of gate lines include a first gate line and a dummy gate line disposed between the data driving circuit and the first gate line.

4. The display device of claim 3, wherein at least one white subpixel having the flip structure among white subpixels disposed in a first row closest to the data driving circuit among the plurality of white subpixels is connected to the dummy gate line.

5. The display device of claim 4, wherein a straight-line distance between a subpixel circuit portion of the white subpixel connected to the dummy gate line and the data driving circuit is less than a straight-line distance between subpixel circuit portions of remaining white subpixels except for the white subpixel connected to the dummy gate line among the white subpixels disposed in the first row and the data driving circuit.

6. The display device of claim 4, wherein:
one white subpixel and three color subpixels corresponding to different colors among the plurality of subpixels form one unit pixel; and
the three color subpixels in the unit pixel include a first color subpixel corresponding to a first color, a second color subpixel corresponding to a second color, and a third color subpixel corresponding to a third color.

7. The display device of claim 6, wherein at least three different gate lines are disposed in the unit pixel.

8. The display device of claim 7, wherein:
subpixels disposed in the first row among the plurality of subpixels form a first pixel group;
subpixels disposed in a second row among the plurality of subpixels form a second pixel group; and
the plurality of gate lines include the dummy gate line disposed in the first pixel group and the second pixel group, and first-to-sixth gate lines.

9. The display device of claim 8, wherein:
the first pixel group includes a first unit pixel to a sixth unit pixel sequentially disposed in the row direction; and
a white subpixel in a third unit pixel among the first unit pixel to the sixth unit pixel is connected to the dummy gate line.

10. The display device of claim 6, wherein one color subpixel among the first color subpixel, the second color subpixel, and the third color subpixel has the flip structure.

11. The display device of claim 6, wherein the first color subpixel, the second color subpixel, the white subpixel, and the third color subpixel are sequentially disposed in the row direction in the unit pixel.

12. The display device of claim 11, wherein:
a high-potential voltage line is disposed in an area adjacent to one side of the first color subpixel and an area adjacent to another side of the third color subpixel on the display panel; and
a sensing line is disposed in an area located between another side of the second color subpixel and one side of the one white subpixel.

13. The display device of claim 12, wherein the sensing line is connected to a branch line passing through emission areas of each of the first color subpixel, the second color subpixel, the one white subpixel, and the third color subpixel.

14. The display device of claim 1, wherein each of the plurality of data lines includes three sub data lines branched to supply the data voltage to each of three subpixels corresponding to the same color and adjacent in the row direction.

15. The display device of claim 14, wherein the plurality of color subpixels include a plurality of red subpixels corresponding to a red color, a plurality of green subpixels corresponding to a green color, and a plurality of blue subpixels corresponding to a blue color.

16. The display device of claim 15, wherein the plurality of data lines include at least one white data line connected to the plurality of white subpixels, at least one red data line connected to the plurality of red subpixels, at least one green data line connected to the plurality of green subpixels, and at least one blue data line connected to the blue subpixels.

17. A display panel comprising:
a plurality of unit pixels disposed in a row closest to a data driving circuit, each of the unit pixels including a white subpixel and at least one color subpixel;
a plurality of gate lines each connected to at least one corresponding unit pixel among the plurality of unit pixels; and
a plurality of data lines each connected to at least one corresponding unit pixel among the plurality of unit pixels,
wherein:
the plurality of unit pixels include a first unit pixel, a second unit pixel, a third unit pixel, a fourth unit pixel, a fifth unit pixel, and a sixth unit pixel;
the plurality of data lines include a first white data line and at least one first color data line each connected to the white subpixel and the at least one color subpixel in the first unit pixel to the third unit pixel, and a second white data line and at least one second color data line each connected to the white subpixel and the at least one color subpixel in the fourth unit pixel to the sixth unit pixel; and
one white subpixel of two adjacent white subpixels in the first unit pixel to the sixth unit pixel has a flip structure in which positions of an emission area and a subpixel circuit portion are inverted.

18. The display device of claim 17, wherein one color subpixel of three adjacent color subpixels corresponding to the same color in the first unit pixel to the sixth unit pixel has the flip structure, and remaining two color subpixels of the three adjacent color subpixels has the normal arrangement structure.

19. The display panel of claim 17, wherein:
the plurality of gate lines include first-to-third gate lines and a dummy gate line disposed between the data driving circuit and the first gate line; and
the dummy gate line is connected to the white subpixel in the third unit pixel.
